(19) United States
(12) Patent Application Publication
(10) Pub. No.: US 2023/0065002 A1
(43) Pub. Date: Mar. 2, 2023

(54) Programmable Control of Signal Characteristics of Pins of Integrated Circuit Memory Chips

(71) Applicant: Micron Technology, Inc., Boise, ID (US)

(72) Inventors: Robert Richard Noel Bielby, Placerville, CA (US); Poorna Kale, Folsom, CA (US)

(21) Appl. No.: 17/463,379

(22) Filed: Aug. 31, 2021

(51) Int. Cl. G11C 7/22

(52) U.S. Cl. CPC G11C 7/222

(57) ABSTRACT

A device having a plurality of pins configured to connect circuits within an integrated circuit package to circuits outside of the integrated circuit package. A driver, enclosed within the package, is programmable to adjust the strength, delay, and/or slew rate of the signals driven onto a pin of the device to represent a predetermined bit of data. Such aspects of the signals driven by the driver according to the programmed settings can be adjusted to reduce energy consumption, electromagnetic interference, and/or errors in receiving the data transmitted via the pin. The settings can be programmed into registers enclosed in the integrated circuit package to control the driver and/or dynamically adjusted using an artificial intelligent engine to optimize a cost function.

### TECHNICAL FIELD

At least some embodiments disclosed herein relate to memory systems in general and more particularly, but not limited to techniques to control signal characteristics of pins of a memory chip.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The embodiments are illustrated by way of example and not limitation in the figures of the accompanying drawings in which like references indicate similar elements.

FIG. 1 shows an integrated circuit memory chip having programmable registers configured to control characteristics of signals driven on pins of the chip according to one embodiment.

FIG. 2 illustrates an implementation of programmable input and output signal characteristics for pins of an integrated circuit chip according to one embodiment.

FIG. 3 shows a system having programmable pin drivers and/or receivers according to one embodiment.

FIG. 4 shows a method to control pin signal characteristics of an integrated circuit chip according to one embodiment.

FIG. 5 illustrates an example computing system having a memory sub-system in accordance with some embodiments of the present disclosure.

FIG. 6 illustrates an integrated circuit memory device configured according to one embodiment.

FIG. 7 is a block diagram of an example computer system in which embodiments of the present disclosure can operate.

### DETAILED DESCRIPTION

At least some aspects of the present disclosure are directed to an integrated circuit memory chip having programmable control of characteristics of signals at input/output pins.

It is a challenge to design a memory chip that works well in various environments for interfacing with different host devices and/or bus loads. A traditional memory device uses an output buffer with a fixed drive strength to generate output signals at its pins. Such a device can deliver either too much drive strength to a given output, or an insufficient level. When an input/output buffer delivers too much drive relative to the requisite load, the resulting signal at the load can experience overshoot, leading to excessive amounts of radiated emissions and Electromagnetic Interference (EMI). Managing Electromagnetic Interference (EMI) at a system level without the ability to reduce the drive strength can be quite complex and cumbersome, leading to modifications in the Printed Circuit Board (PCB) path between the driving device and the receiving device. In the process of modifying the layout of Printed Circuit Board (PCB) to address one offending transmission line, there is an equivalent opportunity to affect a different transmission line/PCB trace as a fallout of the re-routing exercise for the Printed Circuit Board (PCB). When the driving signal is under-powered, a similar exercise of addressing the PCB layout is undertaken with the same potential consequences as seen in the case of addressing the previous, overdrive case.

At least some aspects of the present disclosure address the above and other deficiencies and/or challenges by a programmable control of driving or receiving the signals at a pin of an integrated circuit memory chip. The signals provided via a pin of an integrated circuit chip can be configured to be driven by a programmable driver such that at least some characteristics of the signals can be adjusted for best results in a particular application/environment.

For example, a programmable driver can be configured in a memory chip to drive the signal on a pin based on user programmed parameters. The programmable parameters can be selected to achieve optimized results in a particular system in which the memory chip is installed and/or based on user-defined objectives for the system.

Optionally, the programmable driver can be adjusted continuously to adapt to the operating condition of the memory chip and the system in which the memory chip is installed.

For example, an Artificial Intelligence (AI) engine can be used to determine, based on measured environment parameters (e.g., temperature, input/output activity pattern), the optimized drive strength aligned to a desired cost function. The cost function can be configured to implement tradeoff between radiated Electromagnetic Interference (EMI) and signal integrity, where downstream Error Correction Code (ECC) is used to offset the impact of a somewhat degenerated signaling level. The Artificial Intelligence (AI) engine can optionally inspect data patterns across a set of output pins of a memory chip and use machine learning to modulate the current drive strength accordingly.

Optionally, not only the driving strength of the driver of a pin is programmable, other aspects or characteristics of the signal driven on the pin by the driver can also be programmable, such as delay, slew rate, etc.

For example, signal delay can be used to manage Electromagnetic Interference (EMI). Electromagnetic Interference (EMI) emissions are at their greatest when all outputs of a given device are simultaneously switching. Applying different delays to different pins can prevent simultaneously switching and reduce the magnitude of maximum peak Electromagnetic Interference (EMI) emissions. Staggering the timing of the output signals in time on a pin-by-by basis through the addition of a programmable delay can reduce radiated EMI considerably.

Like the programmable drive strength, the user can either program a fixed delay on a pin-by-pin basis or use an Artificial Intelligence (AI) engine to determine optimized delay based on a desired cost function.

Optionally, the programmable output delay can be used to offset the skew associated with routing of large buses across a Printed Circuit Board (PCB) while trying to achieve uniform timing across that bus. To achieve uniform timing Without a programmable output delay on a pin-by-pin basis, it is possible to achieve the uniform timing by matching effective trace lengths on Printed Circuit Board (PCB) layout with a high degree of accuracy. As the system level clock frequencies continue to increase and the bus width of associated buses increases, the challenge and cost of aligning Printed Circuit Board (PCB) traces with a high degree of accuracy increases tremendously.

Programmable slew rate can also be used to address Electromagnetic Interference (EMI). While a buffer with a high slew rate leads to a very fast “clock to output” response time, it comes at the expense of a very high differential voltage (change in voltage vs. time) which also leads to a high level of radiated emissions. Reducing the slew rate can reduce Electromagnetic Interference (EMI).

For example, a programmable drive circuit can contain a series of taps that are configured to correspond to a given slew rate.

Similar to the use of programmable drive strength and programmable output delay, an Artificial Intelligence (AI) engine can be used to control the slew rate that is optimized for a particular application and/or system in which the memory chip is installed.

The programmable driver of pins can be used not only for integrated circuit memory chips, but also in integrated circuit chips having deep learning accelerators, System on a Chip (SoC), etc., that have very large buses (256 bits wide), which can be unwieldy when managing EMI and overall signal integrity.

Implementing the programmable pin driver within the integrated circuit package can greatly simplify the cost associated with system integration on a Printed Circuit Board (PCB). In many cases, Electromagnetic Interference (EMI) management without such solutions can lead to the addition of expensive metal shielding in order to reduce to radiated emissions to a level allowed by standards and/or regulations related to Electromagnetic Interference (EMI) and/or electromagnetic compatibility (EMC).

In general, a programmable pin driver can be used to drive signals on a pin of an integrated circuit chip. The characteristics of signals driven on the pin by the driver can be adjusted for best operations in a particular environment, a particular system, a particular application, and/or a particular time period of activities.

For example, the driver strength can be programmed to reduce energy consumption without compromising the ability of the host system to accurately interpret the signals from the pin.

For example, the drive strength of the signal on a pin can be selected from a number of fixed taps for improved interoperability and/or compatibility with a particular host system. The selection can be configured via user programming a register in the integrated circuit chip or via automatic determination using an Artificial Intelligence (AI) engine based on a predetermined cost function.

For example, the drive strength of the signal on a pin can be adjusted via the setting in the registers configured in the integrated circuit chip. For example, the integrated circuit chip can have a programming mode in which the signals on a pin is changed in increments. When a desirable drive strength is applied on the pin, the host system can send a signal to accept the drive strength; and in response the integrated circuit chip stores the current setting of the drive strength for the pin in a non-volatile memory in the integrated circuit chip. Alternatively, the host system can send a command to set the content of the register. For example, the register can be accessible at a predetermined memory address; and the host system can write the setting for the register using a write command that identifies the memory address.

For example, the registers can store settings to control other aspects of signaling characteristics on a pin, such as delay, slew rate, signaling, etc.

Optionally, separate registers can be configured to control individual pins.

Alternatively, pins can be grouped and controlled by respective sets of registers.

In some implementations, an Artificial Intelligence (AI) engine is configured to dynamically adjust the settings of the driver control registers based on sensor data and/or operating condition parameters, such as measured Electromagnetic Interference (EMI) in the system, errors and/or bit error rate detected using an Error Correction Code technique in the data transmitted via the pin signals, system level data error and/or data correction flags, etc.

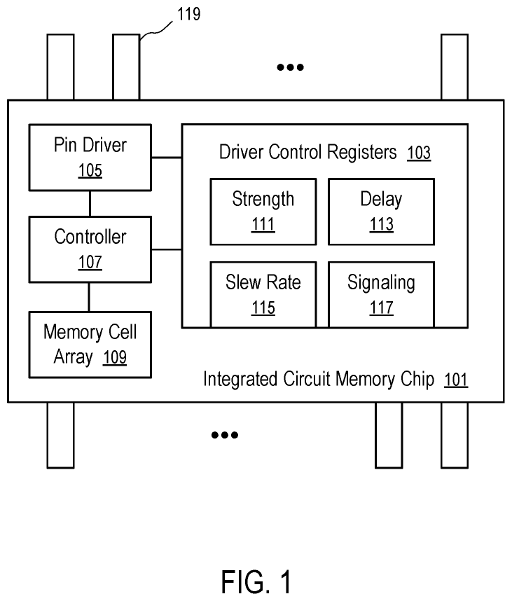

FIG. 1 shows an integrated circuit memory chip 101 having programmable registers 103 configured to control characteristics of signals driven on pins (e.g., 119) of the chip according to one embodiment.

The integrated circuit memory chip 101 is enclosed in an integrated circuit package. The integrated circuit memory chip 101 has one or more memory cell arrays (e.g., 109) formed on one or more integrated circuit dies. The circuits in the integrated circuit memory chip 101 interact with circuits outside of the integrated circuit memory chip 101 through pins (e.g., 119). In some implementations, the pins can be in the form of ball grid array (BGA). For example, the integrated circuit memory chip 101 can be a grid array (BGA) solid state drive (SSD).

The integrated circuit memory chip 101 includes a pin driver 105 configured to drive signals provided on a pin 119. A controller 107 instructs the pin driver 105 to provide signals representative of data stored in the memory cell array 109.

In addition to provide the signals on the pin 119 that are representative of the data stored in the memory cell array 109, the pin driver 105 can be controlled by driver control registers 103 to adjust aspects of the pin signals. While the pin signals are determined by, and thus representative of, the data stored in the memory cell array 109, the adjustable aspects are relevant to the communications of the signals to a receiving device of the signals such that the data represented by the signals can be recovered with reduced energy consumption and/or reduced Electromagnetic Interference (EMI), without errors or without excessive errors that cannot be corrected via an Error Correction Code (ECC) technique.

For example, the strength of the signals driven on the pin 119 by the pin driver 105 can be controlled by one of the driver control registers 103 storing in indication of the customized strength 111 for pin 119. The adjustment of the strength 111 does not change the data represented by the pin driver 105, but can have impact on the Electromagnetic Interference (EMI) associated with signals provided on the pin 119, the energy consumption in providing the signals through the pin 119, and the probability of the signals being incorrectly interpreted by a receiving device connected to the pin 119.

For example, another of the driver control registers 103 can be used to specify a delay 113 of the provision of the signals on the pin 119 relative to a reference signal, such as a clock signal.

For example, a further one of the driver control registers 103 can be used to specify a slew rate 115 of signals driven by the pin driver 105. The slew rate 115 determines the time period between the pin driver 105 starting to drive a signal on the pin 119 and the signal on the pin 119 reaching the strength 111.

For example, other registers in the driver control registers 103 can be used to specify further aspects of signaling 117 for the communication of the data represented by the signals driven on the pin 119.

Individual pins (e.g., 119) can have separate registers to control their signal aspects, such as strength 111, delay 113, slew rate 115, etc. Optionally, the pins (e.g., 119) of the integrated circuit memory chip 101 can be organized in groups; and pins in a group can share a register for specifying one of the aspects (e.g., strength 111, delay 113, or slew rate 115).

Optionally, the driver control registers 103 are accessible via addresses specified using signals applied on address pins of the integrated circuit memory chip 101. Thus, a host system can program the driver control registers 103 by writing data to the corresponding addresses via write commands.

Alternatively, custom commands can be configured to allow a host system to request the integrated circuit memory chip 101 to set the content of the driver control registers 103.

Optionally, the integrated circuit memory chip 101 can be configured to operate in a training mode in which the pin driver 105 is controlled by the controller 107 to drive a signal on the pin using different setting of the registers 103. The host system can select a desirable setting by sending a signal or command to the integrated circuit memory chip 101 when a current setting is desirable.

Optionally, an Artificial Intelligence (AI) engine can be configured to predict optimized settings for the strength 111, the delay 113, the slew rate 115, and/or the signaling 117 based on the current pattern of communications through the pins (e.g., 119) and the operating conditions of the system having the integrated circuit memory chip 101 as a component.

For example, the Artificial Intelligence (AI) engine can be trained, e.g., via an artificial neural network, to establish a predictive model. The model can predict the optimized strength 111, delay 113, slew rate 115 to minimize a cost function that is configured to reduce energy consumption, Electromagnetic Interference (EMI), and error rate associated with the communication using the signals driven by the pin driver 105.

For example, during a training period, signals representative of different patterns of data can be driven by the pin drivers (e.g., 105) using different settings for the strength 111, the delay 113, the slew rate 115, etc. The resulting reductions in energy consumption and Electromagnetic Interference (EMI) can be measured; and the errors detected at the receiving device can be detected via an Error Correction Code (ECC) technique. From the training data, combinations of settings for the driver control registers 103 can be computed to evaluate the cost function; and the optimized combinations for different data patterns can be identified. The identified combinations can be used to train the predictive model to predict optimized settings for the driver control registers 103 in view of a current set of data to be transmitted via the signals driven by the pin drivers (e.g., 105).

The trained predictive model can be installed in the integrated circuit memory chip 101 to generate settings for the driver control registers 103 in view of the data to be transmitted from the memory cell array 109 through the pins (e.g., 119) to the host system.

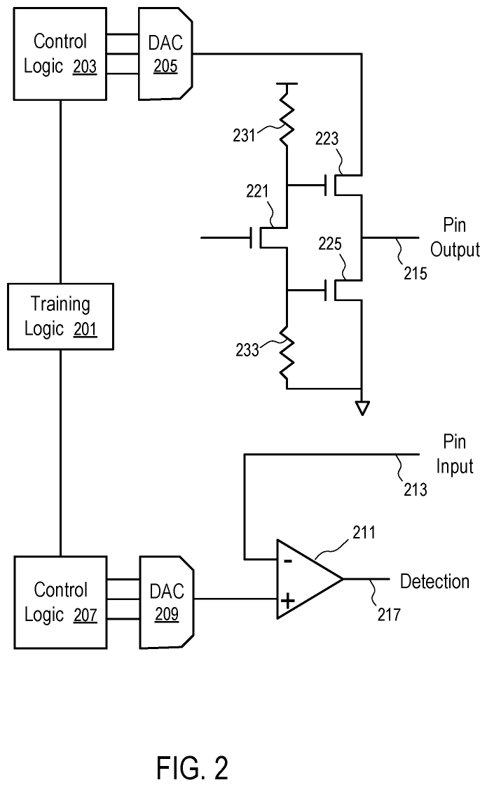

FIG. 2 illustrates an implementation of programmable input and output signal characteristics for pins of an integrated circuit chip according to one embodiment. For example, the technique of FIG. 2 can be implemented in the integrated circuit memory chip 101 of FIG. 1.

In FIG. 2, a pin driver is configured to generate a pin output 215 (e.g., on pin 119 in the Integrated Circuit Memory Chip 101 of FIG. 1). The pin driver has transistors 221, 223, and 225 and resistors 231 and 233. The input to the gate of the transistor 221 controls the data to be sent via the signal generated on the pin output 215. When the input is in one state, the transistor 225 connects the pin output 215 to the ground to represent one bit value (e.g., zero); and when the input is in another state, the transistor 223 connects the pin output 215 to the output of a digital to analog converter 205 to represent another bit value (e.g., one). Thus, the output of the digital to analog converter 205 controls the strength of the signal to be driven on the pin output 215 when such a bit value (e.g., one) is to be transmitted via the pin output 215.

The control logic 203 controls the output level of the digital to analog converter 205. A training logic 201 can be configured to adjust the digital input to the digital to analog converter 205 and thus the driving strength of the pin output 215. When the pin output 215 reaches a suitable strength, the host system connected to the pin output 215 can reliably detect the bit value (e.g., one) signaled on the pin output 215 with reduced Electromagnetic Interference (EMI). In response, the host system can provide a feedback (e.g., via the pin input 213 or another pin), which can cause the training logic 201 to store the digital input to in the driver control registers 103 to indicate the strength 111.

In FIG. 2, a digital to analog converter 209 is controlled by the control logic 207 to adjust the threshold level for detecting input in a pin input 213. A comparator 211 is configured to generate a digital output of detection 217 by comparing the output of the digital to analog converter 209 and the pin input 213. When the pin input 213 is lower than the output of the digital to analog converter 209, the detection 217 provides one bit value (e.g., zero); and when the pin input 213 is higher than the output of the digital to analog converter 209, the detection 217 provides another bit value (e.g., one). Thus, training logic 201 can adjust the digital input provided by the control logic 207 to the digital to analog converter 209 such that the pin input 213 received to represent the bit value (e.g., one) can be reliably detected with a reduced signal strength.

In general, the integrated circuit chip (e.g., 101) can have registers to customize the strength, delay, and slew rate to detect signals in input pins, in addition to registers to customize the strength 111, delay 113, and slew rate 115 to drive signals on output pins. Thus, integrated circuit chips (e.g., 101) can negotiate with each other to settle at signal characteristics (e.g., strength 111, delay 113, and slew rate 115) that optimize a cost function designed to consider the inputs on energy consumption, Electromagnetic Interference (EMI), data error rate, etc.

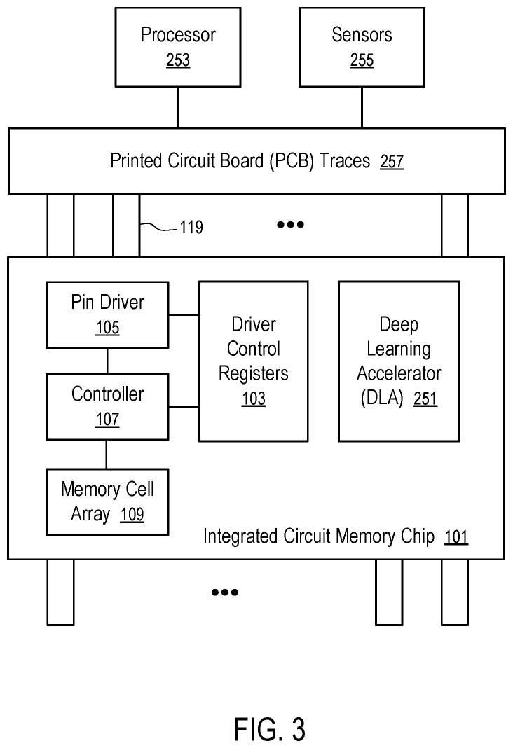

FIG. 3 shows a system having programmable pin drivers and/or receivers according to one embodiment. For example, the integrated circuit memory chip 101 of FIG. 1 can be used in the system of FIG. 3; and the programmable pin driver and receiver of FIG. 2 can be used for the pins of the integrated circuit memory chip 101 and/or the processor 253.

In FIG. 3, the processor 253 and the integrated circuit memory chip 101 are connected via printed circuit board (PCB) traces 257. The system has sensors 255 to measure parameters representing the operational conditions of the system that are relevant to the configurations of the characteristics of signals driven onto the traces 257.

For example, the sensors 255 can measure the level of Electromagnetic Interference (EMI) at various locations in a system of FIG. 3. The Electromagnetic Interference (EMI) can be the result of data transmission between the processor 253 and the integrated circuit memory chip 101 and/or other components.

For example, the pin driver 105 can be controlled by driver control registers 103 to customize the strength 111, delay 113, slew rate 115, and/or other signaling 117 for driving signals on the traces 257 connected to a pin 119.

Similarly, a receiver in the processor 253 and/or a receiver in the integrated circuit memory chip 101 can have registers configurable to adjust its thresholds to adapt to the strength, delay, slew rate and/or other characteristics of signaling for the signals driven on to the traces 257 by the processor 253.

Optionally, the integrated circuit memory chip 101 has a deep learning accelerator 251 having processing units configured to perform matrix operations of computations of an artificial neural network. During a training period, the controller 107 can use different settings for the pin driver 105 to drive signals on the pin 119. The combinations of driver settings and their effects on the sensor measurements, as well as errors in the data transmitted via the signals driven on the pin 119, can be used to identify settings that optimize a cost function for the system in reducing energy consumption, Electromagnetic Interference (EMI), data transmission error, etc. The identified settings in association with their data transmission patterns and the working condition parameters can be used to train an artificial neural network (e.g., using a supervised machine learning technique) to predict the optimized settings for a given data transmission pattern and working condition parameters. Subsequently, the settings of the driver control registers 103 can be adjusted according to the predictions of the trained artificial neural network. Further, during the use of the settings selected using the artificial neural network, the error rates and the sensor measurements can be further collected to further train the artificial neural network to improve its prediction accuracy in optimization of the cost function.

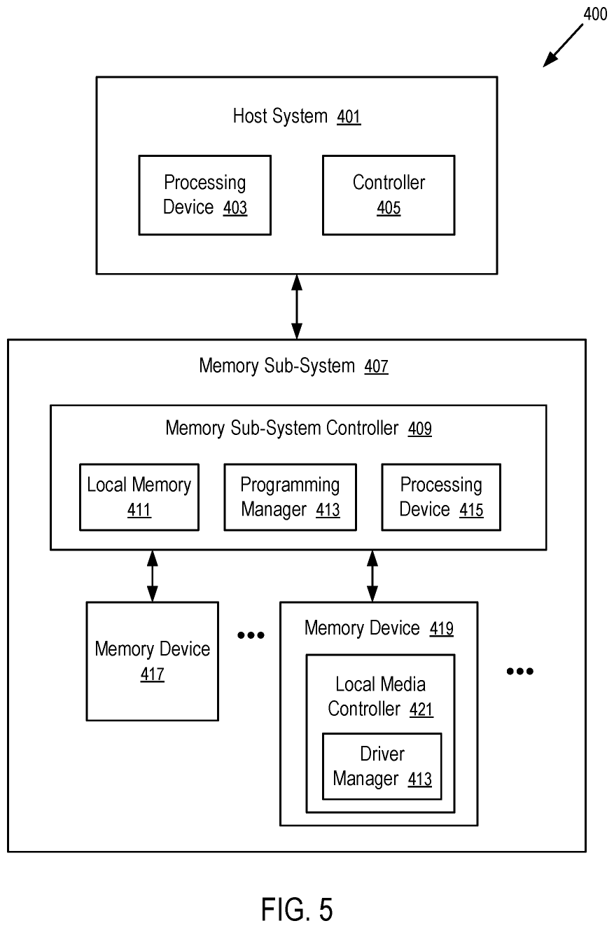

Integrated circuit memory chips can be used in a memory sub-system. Examples of storage devices and memory modules as memory sub-systems are described below in conjunction with FIG. 5. In general, a host system can utilize a memory sub-system that includes one or more components, such as memory devices that store data. The host system can provide data to be stored at the memory sub-system and can request data to be retrieved from the memory sub-system.

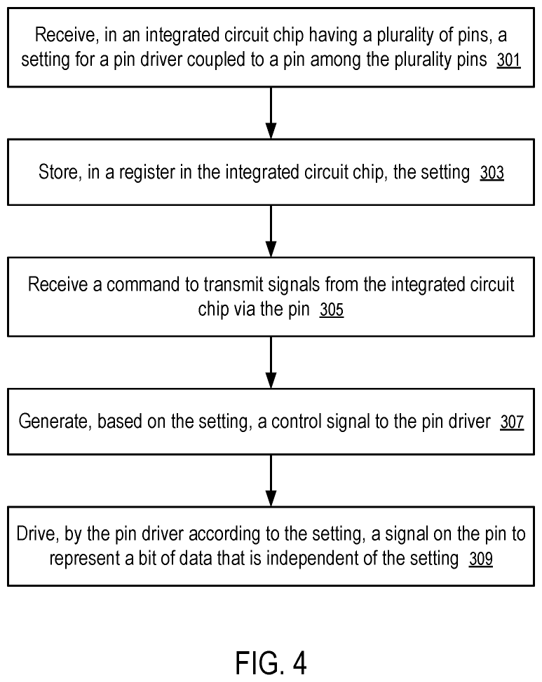

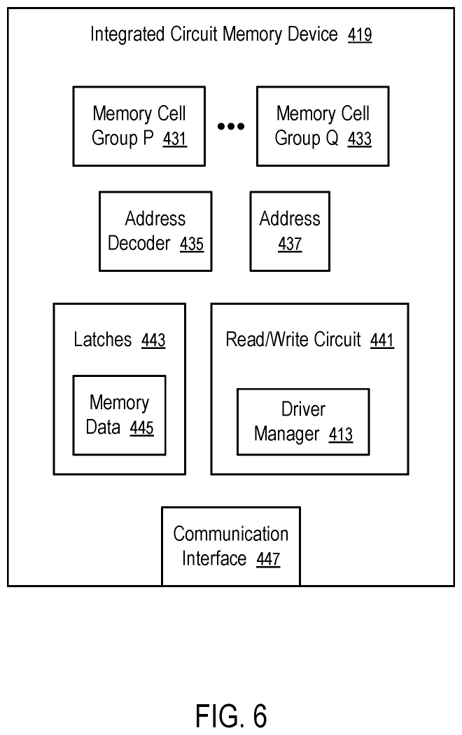

FIG. 4 shows a method to control pin signal characteristics of an integrated circuit chip according to one embodiment. The methods can be performed by processing logic that can include hardware (e.g., processing device, circuitry, dedicated logic, programmable logic, microcode, hardware of a device, integrated circuit, etc.), software/firmware (e.g., instructions run or executed on a processing device), or a combination thereof. In some embodiments, the method is performed at least in part by the controller 409 of FIG. 5, processing logic in the memory device 419 of FIG. 6, and/or the processing device 403 of the host system 401 of FIG. 5. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

For example, the method of FIG. 4 can be performed by a driver manager in an integrated circuit memory chip 101 of FIG. 1 or FIG. 3, with a driver implemented using a technique of FIG. 2.

At block 301, an integrated circuit chip (e.g., 101) having a plurality of pins (e.g., 119) receives a setting for a pin driver 105 coupled to a pin 119 among the plurality pins.

For example, an integrated circuit memory chip 101 has an integrated circuit package configured to enclose the first circuits of the integrated circuit memory chip 101. Pins (e.g., 119) are configured to connect the first circuits, enclosed within the integrated circuit package, to second circuits located outside of the integrated circuit package. For example, the second circuits can include printed circuit board traces connecting the pins (e.g., 119) to a processor 253; and the first circuits can include a memory cell array 109, pin drivers (e.g., 105), a controller 107, registers 103, and/or a deep Learning Accelerator 251. The integrated circuit memory chip 101 has a memory cell array 109. In response to a read command from the processor 253, the pin driver 105 can drive onto a first pin 119, among the pins of the integrated circuit memory chip 101, signals representative of data retrieved from the memory cell array 109. The integrated circuit memory chip 101 has registers 103 programmable to store first settings for the driver 105.

At block 303, the integrated circuit chip (e.g., 101) stores, in a register (e.g., 103) the setting.

For example, the registers 103 can include a first register programmable to store a first parameter; and a strength 111 of first signals driven by the pin driver 105 is controlled by the first parameter.

For example, the first signals are representative of data of a predetermined bit value (e.g., 1) that is independent of the first parameter. How the predetermined bit value (e.g., 1) is represented by the first signals is controlled at least in part by the strength 111 of first signals and thus the first parameter.

For example, the registers 103 can further include a second register programmable to store a second parameter; and a delay 113 between the first signals and a reference signal (e.g., a clock signal) is controlled by the second parameter.

For example, the register 103 can further include a third register programmable to store a third parameter; and a slew rate 115 of the first signals is controlled by the third parameter.

At block 305, a command is received to transmit signals from the integrated circuit chip (e.g., 101) via the pin 119.

At block 307, the integrated circuit chip (e.g., 101) generates, based on the setting, a control signal to the pin driver 105.

For example, the integrated circuit chip (e.g., 101) has a digital to analog converter 205 configured to provide an output that controls the strength of the first signals on the pin output 215 in FIG. 2, when the predetermined bit value (e.g., 1) causes the driver 105 to connect the pin output 215 to the output of the digital to analog converter 205.

At block 309, the pin driver 105 drives according to the setting, a signal on the pin to represent a bit of data that is independent of the setting.

Optionally, the integrated circuit chip (e.g., 101) has a pin receiver that can detect data transmitted via signals having programmable aspects/characteristics, such as strength, delay, or slew rate, or any combination thereof.

For example, the pin receiver can have a comparator 211 having a first input and a second input. The first input of the comparator 211 is connected to a second pin, among the pins of the integrated circuit chip (e.g., 101), to receive pin input 213 and to detect a signal received in the second pin. A digital to analog converter 209 is configured to provide an output that is connected to the second input of the comparator 211. The comparator 211 is configured to generate a digital output (e.g., detection 217) represented by the signal received in the second pin. For example, when the voltage on the pin input 213 is higher than the output of the digital to analog converter 209, the signal provided on the pin input 213 is detected to represent a first bit value (e.g., 1); otherwise, the signal provided on the pin input 213 is detected to represent a second bit value (e.g., 0).

For example, the integrated circuit chip (e.g., 101) can have second registers programmable to store second settings for the pin receiver. The second settings are configured to control data detection based on adjustable characteristics of second signals received in a second pin to which the pin receiver is connected. The adjustable characteristics can include signal strength, delay, and/or slew rate.

For example, the integrated circuit chip (e.g., 101) can be mounted on a printed circuit board that has traces 257. The pins (e.g., 119) of the integrated circuit chip (e.g., 101) are connected by the traces 257 to the pins of a host system, such as a processor 253. A sensor 255 of an apparatus having the processor 253, the printed circuit board, and the integrated circuit chip (e.g., 101) can measure parameters that characterizes the operating condition of the apparatus, such as energy consumption, Electromagnetic Interference, temperature, etc. The setting the programmable pin driver 105 (e.g., strength 111, delay 113, or slew rate 115) can be determined/predicted at least in part based on the measurements of the sensor 255 to optimize the apparatus according to a cost function.

For example, the sensor 255 is configured to measure electromagnetic interference at a location within the apparatus. An artificial neural network can be trained to predict a setting that optimizes a cost function for an operating condition identified by a measurement from the sensor 255 and a pattern of data to be transmitted from the integrated circuit chip (e.g., 101).

For example, after receiving, from the sensor 255, a measurement representative of an operating condition of the apparatus in which the integrated circuit chip (e.g., 101) is mounted, the artificial neural network can predict, using an artificial intelligent engine, the setting to optimize a cost function for the operating condition. The setting can be strength, delay and/or slew rate for the signals driven by the pin driver 105 onto the pin 119.

For example, to train the artificial neural network, the apparatus can measure effects of variations of settings applied to the driver control registers 103. Based on the effects, settings that optimize a cost function under various conditions can be identified to train the artificial neural network to generate a predictive module for the artificial intelligent engine.

For example, the cost function can be configured to reduce energy consumption, electromagnetic interference, and errors in data transmitted via signals driven by the pin driver 105 controlled by the settings of strength, delay and/or slew rate.

FIG. 5 illustrates an example computing system 400 that includes a memory sub-system 407 in accordance with some embodiments of the present disclosure. The memory sub-system 407 can include media, such as one or more volatile memory devices (e.g., memory device 417), one or more non-volatile memory devices (e.g., memory device 419), or a combination of such.

A memory sub-system 407 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 400 can be a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or such a computing device that includes memory and a processing device.

The computing system 400 can include a host system 401 that is coupled to one or more memory sub-systems 407. FIG. 5 illustrates one example of a host system 401 coupled to one memory sub-system 407. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 401 can include a processor chipset (e.g., processing device 403) and a software stack executed by the processor chipset. The processor chipset can include one or more cores, one or more caches, a memory controller (e.g., controller 405) (e.g., NVDIMM controller), and a storage protocol controller (e.g., PCIe controller, SATA controller). The host system 401 uses the memory sub-system 407, for example, to write data to the memory sub-system 407 and read data from the memory sub-system 407.

The host system 401 can be coupled to the memory sub-system 407 via a physical host interface. Examples of a physical host interface include, but are not limited to, a serial advanced technology attachment (SATA) interface, a peripheral component interconnect express (PCIe) interface, a universal serial bus (USB) interface, a Fibre Channel, a Serial Attached SCSI (SAS) interface, a double data rate (DDR) memory bus interface, a Small Computer System Interface (SCSI), a dual in-line memory module (DIMM) interface (e.g., DIMM socket interface that supports Double Data Rate (DDR)), an Open NAND Flash Interface (ONFI), a Double Data Rate (DDR) interface, a Low Power Double Data Rate (LPDDR) interface, or any other interface. The physical host interface can be used to transmit data between the host system 401 and the memory sub-system 407. The host system 401 can further utilize an NVM Express (NVMe) interface to access components (e.g., memory devices 419) when the memory sub-system 407 is coupled with the host system 401 by the PCIe interface. The physical host interface can provide an interface for passing control, address, data, and other signals between the memory sub-system 407 and the host system 401. FIG. 5 illustrates a memory sub-system 407 as an example. In general, the host system 401 can access multiple memory sub-systems via a same communication connection, multiple separate communication connections, and/or a combination of communication connections.

The processing device 403 of the host system 401 can be, for example, a microprocessor, a central processing unit (CPU), a processing core of a processor, an execution unit, a System on a Chip (SoC), etc. In some instances, the controller 405 can be referred to as a memory controller, a memory management unit, and/or an initiator. In one example, the controller 405 controls the communications over a bus coupled between the host system 401 and the memory sub-system 407. In general, the controller 405 can send commands or requests to the memory sub-system 407 for desired access to memory devices 419, 417. The controller 405 can further include interface circuitry to communicate with the memory sub-system 407. The interface circuitry can convert responses received from memory sub-system 407 into information for the host system 401.

The controller 405 of the host system 401 can communicate with controller 409 of the memory sub-system 407 to perform operations such as reading data, writing data, or erasing data at the memory devices 419, 417 and other such operations. In some instances, the controller 405 is integrated within the same package of the processing device 403. In other instances, the controller 405 is separate from the package of the processing device 403. The controller 405 and/or the processing device 403 can include hardware such as one or more integrated circuits (ICs) and/or discrete components, a buffer memory, a cache memory, or a combination thereof. The controller 405 and/or the processing device 403 can be a microcontroller, special purpose logic circuitry (e.g., a field programmable gate array (FPGA), an application specific integrated circuit (ASIC), etc.), or another suitable processor.

The memory devices 419, 417 can include any combination of the different types of non-volatile memory components and/or volatile memory components. The volatile memory devices (e.g., memory device 417) can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 419 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 419 can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, and/or a PLC portion of memory cells. The memory cells of the memory devices 419 can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device 419 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 409 (or controller 409 for simplicity) can communicate with the memory devices 419 to perform operations such as reading data, writing data, or erasing data at the memory devices 419 and other such operations (e.g., in response to commands scheduled on a command bus by controller 405). The controller 409 can include hardware such as one or more integrated circuits (ICs) and/or discrete components, a buffer memory, or a combination thereof. The hardware can include digital circuitry with dedicated (e.g., hard-coded) logic to perform the operations described herein. The controller 409 can be a microcontroller, special purpose logic circuitry (e.g., a field programmable gate array (FPGA), an application specific integrated circuit (ASIC), etc.), or another suitable processor.

The controller 409 can include a processing device 415 (e.g., processor) configured to execute instructions stored in a local memory 411. In the illustrated example, the local memory 411 of the controller 409 includes an embedded memory configured to store instructions for performing various processes, operations, logic flows, and routines that control operation of the memory sub-system 407, including handling communications between the memory sub-system 407 and the host system 401.

In some embodiments, the local memory 411 can include memory registers storing memory pointers, fetched data, etc. The local memory 411 can also include read-only memory (ROM) for storing micro-code. While the example memory sub-system 407 in FIG. 5 has been illustrated as including the controller 409, in another embodiment of the present disclosure, a memory sub-system 407 does not include a controller 409, and can instead rely upon external control (e.g., provided by an external host, or by a processor or controller separate from the memory sub-system).

In general, the controller 409 can receive commands or operations from the host system 401 and can convert the commands or operations into instructions or appropriate commands to achieve the desired access to the memory devices 419. The controller 409 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 419. The controller 409 can further include host interface circuitry to communicate with the host system 401 via the physical host interface. The host interface circuitry can convert the commands received from the host system into command instructions to access the memory devices 419 as well as convert responses associated with the memory devices 419 into information for the host system 401.

The memory sub-system 407 can also include additional circuitry or components that are not illustrated. In some embodiments, the memory sub-system 407 can include a cache or buffer (e.g., DRAM) and address circuitry (e.g., a row decoder and a column decoder) that can receive an address from the controller 409 and decode the address to access the memory devices 419.

In some embodiments, the memory devices 419 include local media controllers 421 that operate in conjunction with memory sub-system controller 409 to execute operations on one or more memory cells of the memory devices 419. An external controller (e.g., memory sub-system controller 409) can externally manage the memory device 419 (e.g., perform media management operations on the memory device 419). In some embodiments, a memory device 419 is a managed memory device, which is a raw memory device combined with a local controller (e.g., local media controller 421) for media management within the same memory device package. An example of a managed memory device is a managed NAND (MNAND) device.

The controller 409 and/or a memory device 419 can include a driver manager 413 configured to control pin signal characteristics of an integrated circuit chip. In some embodiments, the controller 409 in the memory sub-system 407 and/or the controller 421 in the memory device 419 can include at least a portion of the driver manager 413. In other embodiments, or in combination, the controller 405 and/or the processing device 403 in the host system 401 includes at least a portion of the driver manager 413. For example, the controller 409, the controller 405, and/or the processing device 403 can include logic circuitry implementing the driver manager 413. For example, the controller 409, or the processing device 403 (e.g., processor) of the host system 401, can be configured to execute instructions stored in memory for performing the operations of the driver manager 413 described herein. In some embodiments, the driver manager 413 is implemented in an integrated circuit chip disposed in the memory sub-system 407. In other embodiments, the driver manager 413 can be part of firmware of the memory sub-system 407, an operating system of the host system 401, a device driver, or an application, or any combination therein.

For example, the driver manager 413 implemented in the controller 409 and/or the controller 421 can be configured via instructions and/or logic circuit to control pin signal characteristics of an integrated circuit chip.

FIG. 6 illustrates an integrated circuit memory device configured according to one embodiment. For example, the memory devices 419 in the memory sub-system 407 of FIG. 5 can be implemented using the integrated circuit memory device 419 of FIG. 6.

The integrated circuit memory device 419 can be enclosed in a single integrated circuit package. The integrated circuit memory device 419 includes multiple groups 431, . . . , 433 of memory cells that can be formed in one or more integrated circuit dies. A typical memory cell in a group 431 (or group 433) can be programmed to store one or more bits of data.

Some of the memory cells in the integrated circuit memory device 419 can be configured to be operated together for a particular type of operations. For example, memory cells on an integrated circuit die can be organized in planes, blocks, and pages. A plane contains multiple blocks; a block contains multiple pages; and a page can have multiple strings of memory cells. For example, an integrated circuit die can be the smallest unit that can independently execute commands or report status; identical, concurrent operations can be executed in parallel on multiple planes in an integrated circuit die; a block can be the smallest unit to perform an erase operation; and a page can be the smallest unit to perform a data program operation (to write data into memory cells). Each string has its memory cells connected to a common bitline; and the control gates of the memory cells at the same positions in the strings in a block or page are connected to a common wordline. Control signals can be applied to wordlines and bitlines to address the individual memory cells.

The integrated circuit memory device 419 has a communication interface 447 to receive a command having an address 437 from the controller 409 of a memory sub-system 407, retrieve memory data 445 from memory cells identified by the memory address 437, and provide at least the memory data 445 as part of a response to the command. Optionally, the memory device 419 may decode the memory data 445 (e.g., using an error-correcting code (ECC) technique) and provide the decoded data as part of a response to the command. An address decoder 435 of the integrated circuit memory device 419 converts the address 437 into control signals to select a group of memory cells in the integrated circuit memory device 419; and a read/write circuit 441 of the integrated circuit memory device 419 performs operations to determine the memory data 445 stored in the memory cells at the address 437.

The integrated circuit memory device 419 has a set of latches 443, or buffers, to hold memory data 445 temporarily while the read/write circuit 441 is programming the threshold voltages of a memory cell group (e.g., 431 or 433) to store data, or evaluating the threshold voltages of a memory cell group (e.g., 431 or 433) to retrieve data.

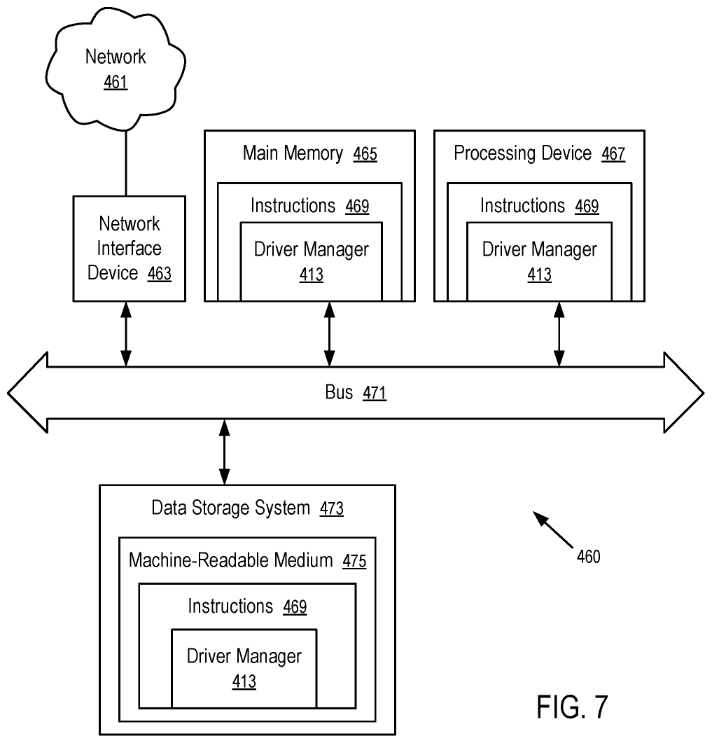

FIG. 7 illustrates an example machine of a computer system 460 within which a set of instructions, for causing the machine to perform any one or more of the methodologies discussed herein, can be executed. In some embodiments, the computer system 460 can correspond to a host system (e.g., the host system 401 of FIG. 5) that includes, is coupled to, or utilizes a memory sub-system (e.g., the memory sub-system 407 of FIG. 5) or can be used to perform the operations of a driver manager 413 (e.g., to execute instructions to perform operations corresponding to the driver manager 413 described with reference to FIG. 1 to FIG. 6). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 460 includes a processing device 467, a main memory 465 (e.g., read-only memory (ROM), flash memory, dynamic random access memory (DRAM) such as synchronous DRAM (SDRAM) or Rambus DRAM (RDRAM), static random access memory (SRAM), etc.), and a data storage system 473, which communicate with each other via a bus 471 (which can include multiple buses).

The processing device 467 can be one or more general-purpose processing devices such as a microprocessor, a central processing unit, or the like. More particularly, the processing device 467 can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 467 can also be one or more special-purpose processing devices such as an application specific integrated circuit (ASIC), a field programmable gate array (FPGA), a digital signal processor (DSP), network processor, or the like. The processing device 467 is configured to execute instructions 469 for performing the operations and steps discussed herein. The computer system 460 can further include a network interface device 463 to communicate over the network 461.

The data storage system 473 can include a machine-readable medium 475 (also known as a computer-readable medium) on which is stored one or more sets of instructions 469 or software embodying any one or more of the methodologies or functions described herein. The instructions 469 can also reside, completely or at least partially, within the main memory 465 and/or within the processing device 467 during execution thereof by the computer system 460, the main memory 465 and the processing device 467 also constituting machine-readable storage media. The machine-readable medium 475, data storage system 473, and/or main memory 465 can correspond to the memory sub-system 407 of FIG. 5.

In one embodiment, the instructions 469 include instructions to implement functionality corresponding to a driver manager 413 (e.g., the driver manager 413 described with reference to FIG. 1 to FIG. 6). While the machine-readable medium 475 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations are described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special purpose circuitry, with or without software instructions, such as using Application-Specific Integrated Circuit (ASIC) or Field-Programmable Gate Array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

1. A device, comprising:
an integrated circuit package;
a set of pins configured to connect first circuits enclosed within the integrated circuit package to second circuits located outside of the integrated circuit package;
memory cells enclosed within the integrated circuit package;
a driver programmable via one or more first settings received from a host system, the driver enclosed within the integrated circuit package and configured to transmit to a first pin, among the pins, signals representative of data retrieved from the memory cells; and
registers enclosed within the integrated circuit package and programmable to store the first settings for the driver based at least in part on signaling received from the host system.

2. The device of claim 1, wherein the registers include a first register programmable to store a first parameter; and wherein a strength of first signals driven by the driver is controlled by the first parameter.

3. The device of claim 2, wherein the first signals are representative of data of a predetermined bit value that is independent of the first parameter.

4. The device of claim 3, further comprising:
a digital to analog converter configured to provide an output that controls the strength of the first signals.

5. The device of claim 4, wherein when the driver is instructed to drive the first signals, the driver is configured to connect the output of the digital to analog converter to the first pin.

6. The device of claim 3, wherein the registers further include a second register programmable to store a second parameter; and wherein a delay between the first signals and a reference signal is controlled by the second parameter.

7. The device of claim 6, wherein the registers further include a third register programmable to store a third parameter; and wherein a slew rate of the first signals is controlled by the third parameter.

8. The device of claim 7, further comprising:
a comparator having a first input and a second input, the first input of the comparator connected to a second pin, among the pins, to detect a signal received in the second pin; and
a digital to analog converter configured to provide an output that is connected to the second input of the comparator, wherein the comparator is configured to generate a digital output represented by the signal received in the second pin.

9. The device of claim 7, further comprising:
a receiver connected to a second pin, among the pins; and
second registers programmable to store second settings for the receiver.

10. The device of claim 9, wherein the second settings are configured to control data detection based on characteristics of second signals received in the second pin, the characteristics including strength, delay, or slew rate, or any combination thereof.

11-20. (canceled)

21. A method, comprising:
connecting, via a set of pins of a device having registers enclosed within an integrated circuit package, first circuits enclosed within the integrated circuit package to second circuits located outside of the integrated circuit package;
transmitting, by a driver enclosed within the integrated circuit package and programmable via one or more first settings received from a host system, to a first pin, among the pins, signals representative of data retrieved from memory cells enclosed within the integrated circuit package; and
storing, in the registers, the first settings for the driver based at least in part on signaling received from the host system.

22. The method of claim 21, wherein the registers include a first register programmable to store a first parameter; and the method further comprises:
controlling, by the first parameter, a strength of first signals driven by the driver.

23. The method of claim 22, wherein the first signals are representative of data of a predetermined bit value that is independent of the first parameter.

24. The method of claim 23, further comprising:
providing, by a digital to analog converter of the device, an output to control the strength of the first signals.

25. The method of claim 24, further comprising:
connecting, by the driver, the output of the digital to analog converter to the first pin, when the driver is instructed to drive the first signals.

26. The method of claim 23, wherein the registers further include a second register programmable to store a second parameter; and the method further comprises:
controlling, by the second parameter, a delay between the first signals and a reference signal.

27. The method of claim 26, wherein the registers further include a third register programmable to store a third parameter; and the method further comprises:
controlling, by the third parameter, a slew rate of the first signals.

28. The method of claim 27, further comprising:
detecting, via a comparator of the device having a first input connected to a second pin and a second input, a signal received in the second pin;
providing, by a digital to analog converter of the device, an output that is connected to the second input of the comparator; and
generating, by the comparator, a digital output represented by the signal received in the second pin.

29. The method of claim 27, further comprising:
storing, in second registers, second settings for a receiver connected to a second pin, among the pins.

30. The method of claim 29, further comprising:
controlling, by the second settings, data detection based on characteristics of second signals received in the second pin, the characteristics including strength, delay, or slew rate, or any combination thereof.
